(19) United States
(12) Patent Application Publication
(10) Pub. No.: US 2026/0362688 A1
(43) Pub. Date: Nov. 12, 2026

(54) Memory Cell, Memory Array Comprising Memory Cells, And Method Of Forming an Array Of Memory Cells

(71) Applicant: Micron Technology, Inc., Boise, ID (US)

(72) Inventors: Pankaj Sharma, Boise, ID (US); Kamal M. Karda, Boise, ID (US)

(73) Assignee: Micron Technology, Inc., Boise, ID (US)

(21) Appl. No.: 19/462,166

(22) Filed: Jan. 28, 2026

Related U.S. Application Data
(60) Provisional application No. 63/785,143, filed on Apr. 8, 2025.

(51) Int. Cl. H10B 41/27; G11C 5/06; H10D 30/68

(52) U.S. Cl. CPC H10B 41/27; G11C 5/063; H10D 30/68

(57) ABSTRACT

A p-type transistor of a memory cell comprises a control gate, charge-storage material, first channel material, charge-blocking material, and charge-passage material. A first source/drain region of an n-type transistor of the memory cell is directly electrically coupled to the charge-storage material. The n-type transistor comprises a gate, a second channel material, and a gate insulator. The control gate of the p-type transistor and the n-type-transistor gate are directly electrically coupled together. A conductive shield line is adjacent the second channel material and not adjacent the first channel material. Other embodiments, including method, are disclosed.

### TECHNICAL FIELD

Embodiments disclosed herein pertain to memory cells, to memory arrays comprising memory cells, and to methods of forming an array of memory cells.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The digitlines may conductively interconnect memory cells along columns of the array, and the access lines may conductively interconnect memory cells along rows of the array. Each memory cell may be uniquely addressed through the combination of a digitline and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A field effect transistor is one type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate. Regardless, the gate insulator may be programmable, for example being ferroelectric.

### BRIEF DESCRIPTION OF THE DRAWINGS

FIG. 1 is a diagrammatic schematic of a memory cell in accordance with an embodiment of the invention.

FIG. 2 is a diagrammatic cross-sectional view of a portion of a construction comprising a memory cell of the schematic of FIG. 1.

FIG. 3 is a diagrammatic schematic view of a memory array in accordance with an embodiment of the invention.

FIGS. 4-17 are diagrammatic cross-sectional views of a process of forming an array of memory cells in accordance with an embodiment of the invention.

### DETAILED DESCRIPTION OF EXAMPLE EMBODIMENTS

Memory cells, memory arrays, and methods in accordance with this disclosure and inventions herein at least in part encompass that which is disclosed in U.S. Patent Application No. 2024/0268091 to Karda et al. Such is included as an Appendix hereto and constitutes a part of this disclosure as if drawings thereof and the text thereof were included in the main body of this disclosure and not as an Appendix.

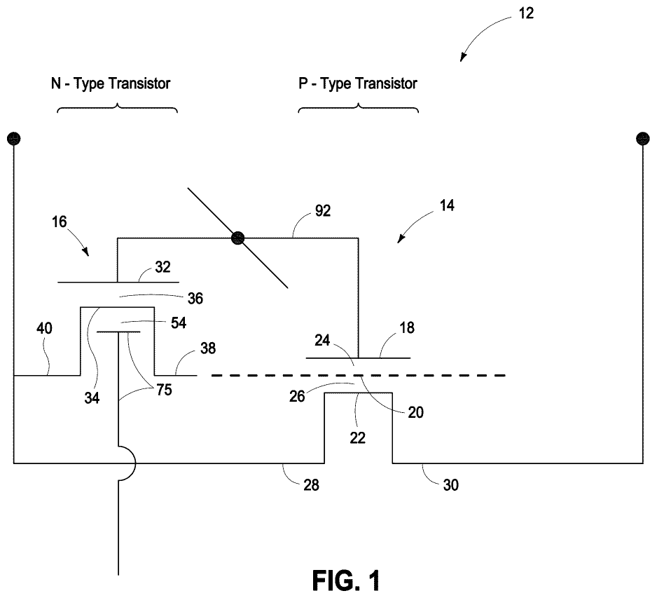

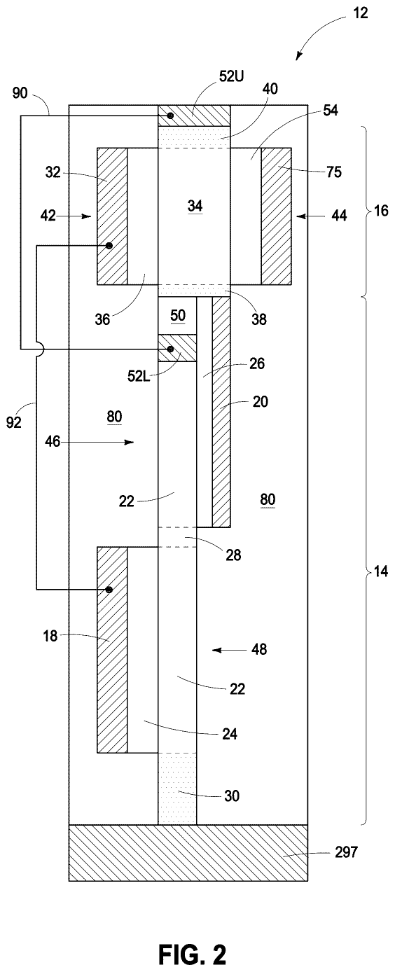

An example memory cell in accordance with embodiments of the invention is initially described with reference to FIGS. 1 and 2 with respect to a construction comprising a memory cell 12. Such comprises a p-type transistor 14 and an n-type transistor 16. P-type transistor 14 comprises a control gate 18, a charge-storage material 20, a first channel material 22, charge-blocking material 24, and charge-passage material 26 between charge-storage material 20 and first channel material 22. P-type transistor 14 may be considered as comprising first and second source/drain regions 28 and 30, respectively. In some embodiments, second source/drain region 30 is referred to as lower source/drain region 30 of p-type transistor 14.

N-type transistor 16 comprises a gate 32, a second channel material 34, and a gate insulator 36 between n-type-transistor gate 32 and second channel material 34. N-type transistor 16 may be considered as comprising first and second source/drain regions 38 and 40, respectively. In some embodiments, first source/drain region 38 is referred to as lower source/drain region 38 of n-type transistor 16. A source/drain region of n-type transistor 16 (e.g., first source/drain region 38) is directly electrically coupled to charge-storage material 20 of p-type transistor 14. Control gate 18 of p-type transistor 14 and n-type-transistor gate 32 are directly electrically coupled together as shown via a schematic line 92 (e.g., schematic line 92 structurally being a shorting connection likely outside of an array area in which a plurality of memory cells 12 are received; e.g., on one of four sides of the array area). In one embodiment and as shown, control gate 18 of p-type transistor 14 and n-type-transistor gate 32 are vertically spaced from one another.

In one embodiment, n-type transistor 16 is directly above p-type transistor 14. Second channel material 34 may be directly above first channel material 22. Insulating material 50 (e.g., silicon dioxide) may be vertically between first and second channel materials 22 and 34 (e.g., as may be first source/drain region 38). A digitline 52* is directly electrically coupled to first channel material 22 of p-type transistor 14, with a portion 52L of digitline 52* being directly under insulating material 50 (an * being used as a suffix to be inclusive of all such same-numerically-designated structures or portions thereof that may or may not have other suffixes).

In one embodiment, n-type transistor 16 may be considered as having a first side 42 and a second side 44, with n-type-transistor gate 32 and gate insulator 36 being on first side 42 of second channel material 34. In one embodiment, charge-storage material 20 and control gate 18 of p-type transistor 14 are on opposite lateral sides 46 and 48 of first channel material 22. In one embodiment, charge-storage material 20 and control gate 18 are vertically spaced from one another and, in one such embodiment, charge-storage material 20 is above, but not directly above, control gate 18. In one embodiment, n-type transistor gate 32 is above, in one embodiment directly above, control gate 18 of p-type transistor 14.

In one embodiment, digitline 52* is directly electrically coupled to second source/drain region 40 of n-type transistor 16 and is electrically coupled through first channel material 22 of p-type transistor 14 to one source/drain region of the p-type transistor (e.g., first source/drain region 28). Digitline 52* comprises an upper portion 52U directly above lower portion 52L, with such upper and lower portions 52U and 52L being shorted/directly electrically coupled together as shown in FIG. 2 via a schematic line 90 (e.g., schematic line 90 likely structurally being a shorting connection likely outside of the array area on another of the four sides that is adjacent the one such side where line/connection 92 is located). Upper portion 52U is directly above and directly electrically coupled to second source/drain region 40. Lower portion 52L is directly against first channel material 22 of p-type transistor 14. In one embodiment, lower portion 52L is directly below second channel material 34, with insulating material 50 vertically separating lower portion 52L and second channel material 34. In one embodiment, upper portion 52U is wider than lower portion 52L and, in embodiment, lower portion 52L is directly against a lateral side of charge-passage material 26 of p-type transistor 14. In one embodiment, second channel material 34 is directly above the one source/drain region (e.g., 28) of p-type transistor 14 and, in one such embodiment, the one source/drain region (e.g., 28) of p-type transistor 14 is also directly above (at least some of) first channel material 22 of p-type transistor 14.

In one embodiment, a conductive shield line 75 is adjacent (e.g., laterally adjacent) second channel material 34 and not adjacent first channel material 22. In one embodiment, conductive shield line 75 is adjacent second channel material 34 on a second side 44 of second channel material 34 that is opposite first side 42 (e.g., regardless of whether second channel material 34 is not adjacent first channel material 22). In one embodiment, insulative material 54 is between conductive shield line 75 and second channel material 34. Two or more shield lines may be shorted together (not shown) likely outside of the array area in which a plurality of memory cells 12 are received (e.g., by a shorting connection on the one of the four sides where line/connections 92 is located).

Second source/drain region 30 of p-type transistor 14 may be directly electrically coupled to a connection 297 that is common to at least some of the plurality of p-type transistors, for example as described in U.S. Patent Application No. 2024/0268091 to Karda et al.

Example insulative material 80 is about memory cell 12 as shown.

Generally speaking, the compositions of the various structures and materials described herein are not necessarily or not particularly material to the inventions disclosed herein, but for of course their inherent or implied electrical properties as respects conductive, insulative, or semiconductive and as may be disclosed in U.S. Patent Application No. 2024/0268091 to Karda et al. The artisan is capable of selecting such compositions and as are disclosed in U.S. Patent Application No. 2024/0268091 to Karda et al.

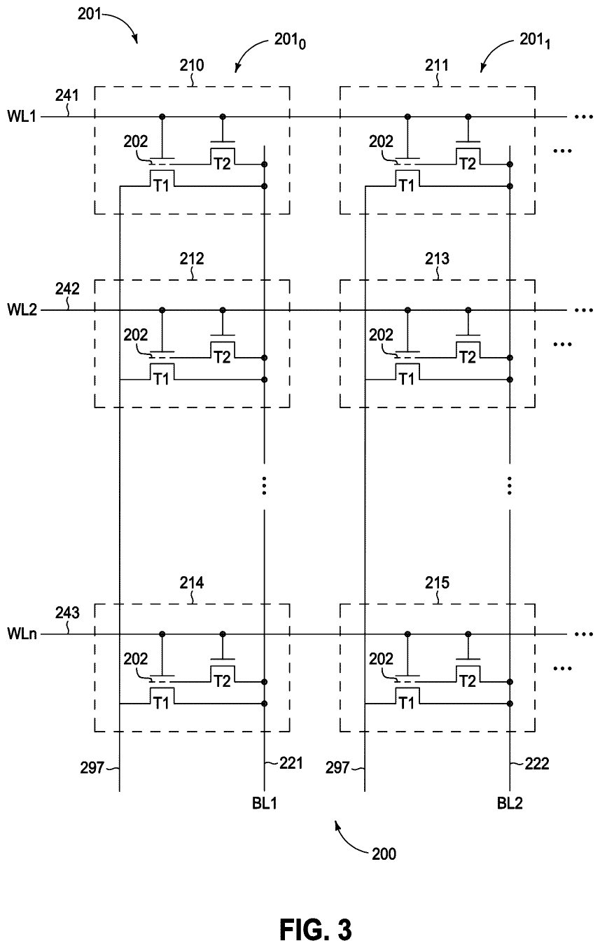

Embodiments as described above may be incorporated in a memory device and in accordance with the schematic diagram of FIG. 3 as taken from U.S. Patent Application No. 2024/0268091 to Karda et al. and showing a portion of a memory device 200 including a memory array 201, according to some embodiments described herein. Example memory device 200 includes memory cells 210 through 215, which are volatile memory cells (e.g., DRAM cells) like memory cell 12 shown in FIGS. 1 and 2. For simplicity, similar or identical elements among memory cells 210 through 215 are given the same labels.

Each of memory cells 210 through 215 includes two transistors T1 and T2. Thus, each of memory cells 210 through 215 can be called a 2T memory cell (e.g., a 2T gain cell). Each of transistors T1 and T2 can include a field-effect transistor (FET). As an example, transistor T1 can be a p-type transistor or p-channel FET (PFET), and transistor T2 can be an n-type transistor or n-channel FET (NFET). Part of transistor T1 can include a structure of a p-channel metal-oxide semiconductor (PMOS) PFET. Thus, transistor T1 can include an operation similar to that of a PMOS transistor. Part of transistor T2 can include an n-channel metal-oxide semiconductor (NMOS). Thus, transistor T2 can include an operation similar to that of an NMOS transistor.

Transistor T1 of memory device 200 includes a charge-storage based structure (e.g., a floating-gate based). As shown in FIG. 3, each of memory cells 210 through 215 includes a charge-storage structure 202, which can include the floating gate of transistor T1. Charge-storage structure 202 can form the memory element of a respective memory cell among memory cells 210 through 215. Charge-storage structure 202 can store charge. The value (e.g., “0” or “1”) of information stored in a particular memory cell among memory cells 210 through 215 can be based on the amount of charge in charge-storage structure 202 of that particular memory cell.

As shown in FIG. 3, transistor T2 (e.g., the channel region of transistor T2) of a particular memory cell among memory cells 210 through 215 can be electrically coupled to (e.g., directly electrically coupled to) charge-storage structure 202 of that particular memory cell. Thus, a circuit path (e.g., current path) can be formed directly between transistor T2 of a particular memory cell and charge-storage structure 202 of that particular memory cell during an operation (e.g., a write operation) of memory device 200.

Memory cells 210 through 215 can be arranged in memory cell groups 201₀ and 201₁. FIG. 3 shows two memory cell groups (e.g., 201₀ and 201₁) as an example. However, memory device 200 can include more than two memory cell groups. Memory cell groups 201₀ and 201₁ can include the same number of memory cells. For example, memory cell group 201₀ can include memory cells 210, 212, and 214, and memory cell group 201₁ can include memory cells 211, 213, and 215. FIG. 3 shows three memory cells in each of memory cell groups 201₀ and 201₁ as an example. The number of memory cells in memory cell groups 201₀ and 201₁ can be different from three.

Memory device 200 can perform a write operation to store information in memory cells 210 through 215, and a read operation to read (e.g., sense) information from memory cells 210 through 215. Memory device 200 can be configured to operate as a DRAM device. However, unlike some conventional DRAM devices that store information in a structure such as a container for a capacitor, memory device 200 can store information in the form of charge in charge-storage structure 202 (which can be a floating gate structure). As mentioned above, charge storage structure 202 can be the floating gate of transistor T1. During an operation (e.g., a read or write operation) of memory device 200, an access line (e.g., a single access line) and a data line/digitline (e.g., a single data line/digitline) can be used to access a selected memory cell (e.g., a target memory cell).

As shown in FIG. 3, memory device 200 can include access lines (e.g., wordlines) 241, 242, and 243 that can carry respective signals (e.g., wordline signals) WL1, WL2, and WLn. Access lines 241, 242, and 243 can be used to access both memory cell groups 201₀ and 201₁. Each of access lines 241, 242, and 243 can be structured as at least one conductive line (one conductive line or multiple conductive lines that can be electrically coupled [e.g., shorted] to each other). Access lines 241, 242, and 243 can be selectively activated (e.g., activated one at a time) during an operation (e.g., read or write operation) of memory device 200 to access a selected memory cell (or selected memory cells) among memory cells 210 through 215. A selected cell can be referred to as a target cell. In a read operation, information can be read from a selected memory cell (or selected memory cells). In a write operation, information can be stored in a selected memory cell (or selected memory cells).

In memory device 200, a single access line (e.g., a single word line) can be used to control (e.g., turn on or turn off) transistors T1 and T2 of a respective memory cell during either a read or write operation of memory device 200. Some conventional memory devices may use multiple (e.g., two separate) access lines to control access to a respective memory cell during read and write operations. In comparison with such conventional memory devices (that use multiple access lines for the same memory cell), memory device 200 uses a single access line (e.g., shared access line) in memory device 200 to control both transistors T1 and T2 of a respective memory cell to access the respective memory cell. This technique can save space and simplify operation of memory device 200. Further, some conventional memory devices may use multiple data lines/digitlines to access a selected memory cell (e.g., during a read operation) to read information from the selected memory cell. In memory device 200, a single data line/digitline (e.g., data line/digitline 221 or 222) can be used to access a selected memory cell (e.g., during a read operation) to read information from the selected memory cell. This may also simplify the structure, operation, or both of memory device 200 in comparison with conventional memory devices using multiple data lines to access a selected memory cell.

In memory device 200, the gate (e.g., control gate) of each of transistors T1 and T2 can be part of a respective access line (e.g., a respective wordline). As shown in FIG. 3, the gate of each of transistors T1 and T2 of memory cells 210 and 211 can be part of access line 241. For example, in the structure of memory device 200, different portions of the material (or materials) that form access line 241 can form respective gates of transistors T1 and T2 of memory cells 210 and 211. In another example, different portions of the material (or materials) that form access line 242 can form respective gates of transistors T1 and T2 of memory cells 212 and 213. In another example, different portions of the material (or materials) that form access line 243 can form respective gates of transistors T1 and T2 of memory cells 214 and 215.

In memory device 200, transistors T1 and T2 of a particular memory cell can share (e.g., can be controlled by) the same access line. For example, transistors T1 and T2 of memory cell 210 can share (e.g., can be controlled by) access line 241. In another example, transistors T1 and T2 of memory cell 212 can share (e.g., can be controlled by) access line 241.

As shown in FIG. 3, memory device 200 can include data lines (e.g., bit lines/digitlines) 221 and 222 that can carry respective signals (e.g., bit line signals) BL1 and BL2. During a read operation, memory device 200 can use data line/digitline 221 to obtain information read (e.g., sensed) from a selected memory cell of memory cell group 201₀, and data line/digitline 222 to read information from a selected memory cell of memory cell group 201₁. During a write operation, memory device 200 can use data line/digitline 221 to provide information to be stored in a selected memory cell of memory cell group 201₀ and data line 222 to provide information to be stored in a selected memory cell of memory cell group 201₁.

Memory device 200 can include a connection 297 coupled to memory cells 210 through 215. Connection 297 can be structured from a conductive plate (e.g., a conductive region; e.g., conductive layer). Connection 297 can be coupled to a ground terminal (e.g., ground plate) of memory device 200. Alternatively, connection 297 can be coupled to a non-ground terminal (e.g., a non-ground potential) of memory device 200. As an example, connection 297 can be a common conductive plate (e.g., formed under the memory cells [e.g., memory cells 210 through 215]) of memory device 200. In this example, the elements (e.g., transistors T1 and T2) of each of the memory cells (e.g., memory cells 210 through 215) of memory device 200 can be formed over (e.g., formed vertically) the common conductive plate.

As shown in FIG. 3, a different portion of connection 297 can be shared by memory cells that are associated with different access lines (e.g., wordlines). For example, a portion of connection 297 can be shared by memory cells 210, 212, and 214 that are associated with access lines 241, 242, and 243, respectively. In another example, another portion of connection 297 can be shared by memory cells 211, 213, and 215 that are associated with access lines 241, 242, and 243, respectively. In another alternative structure of memory device 200, memory cells associated with the same access line can share a portion of connection 297 that is separate from the portion of connection 297 shared by memory cells of other access lines. Sharing portions of connection 297 among memory cells as shown in FIG. 3 can reduce capacitance (e.g., plate capacitance) of conductive structures that form (or that are part of) connection 297. In another alternative structure of memory device 200, memory cells associated with different access lines and different data lines/digitlines can be coupled to the same (e.g., a common conductive plate) connection 297.

As shown in FIG. 3, transistor T1 (e.g., the channel region of transistor T1) of a particular memory cell among memory cells 210 through 215 can be electrically coupled to (e.g., directly electrically coupled to) connection 297 and electrically coupled to (e.g., directly electrically coupled to) a respective data line/digitline (e.g., data line/digitline 221 or 222). Thus, a circuit path (e.g., current path) can be formed between a respective data line/digitline (e.g., data line/digitline 221 or 222) and connection 297 through transistor T1 of a selected memory cell during an operation (e.g., a read operation) performed on the selected memory cell.

Any other attribute(s) or aspect(s) as shown and/or described herein with respect to other embodiments may be used.

Operating, method, and structure aspects may additionally or otherwise be as described and shown in U.S. Patent Application No. 2024/0268091 to Karda et al.

Embodiments of the invention encompass methods used in forming memory circuitry having an array of memory cells, by way of example only, that incorporate device/structure as referred to above. Nevertheless, the method embodiments may incorporate, form, and/or have any of the attributes described with respect to device embodiments.

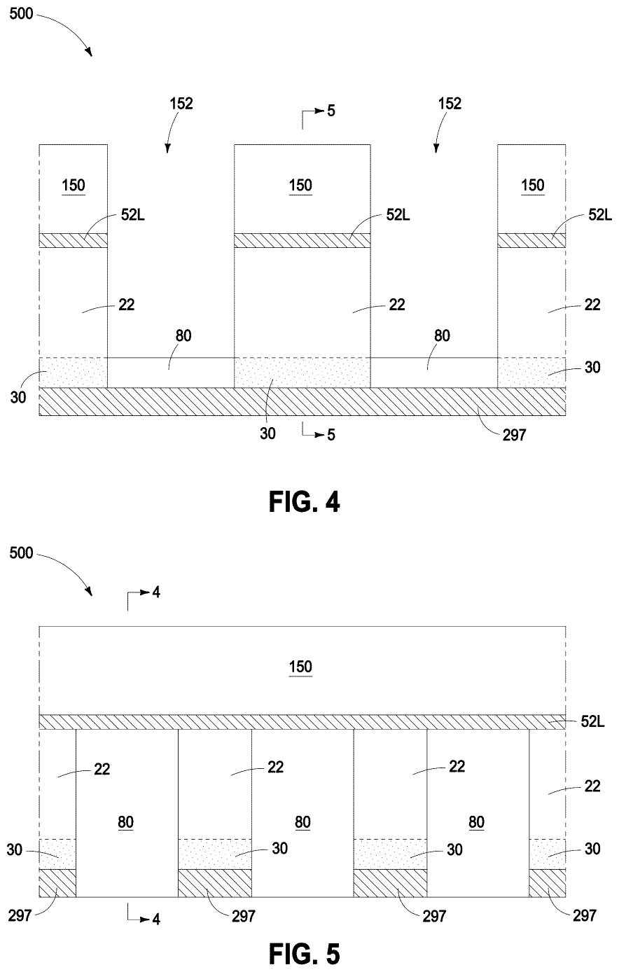

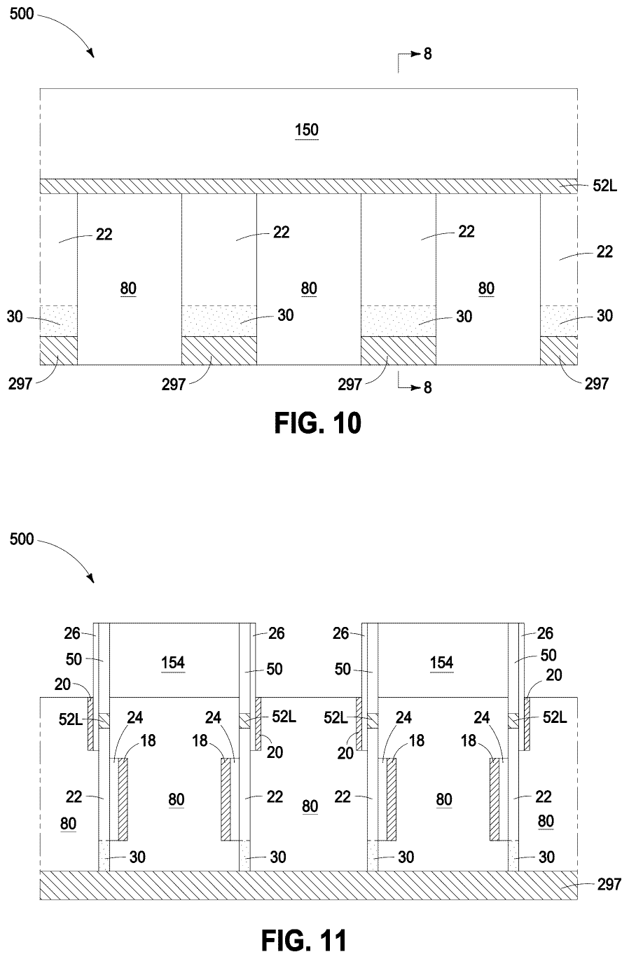

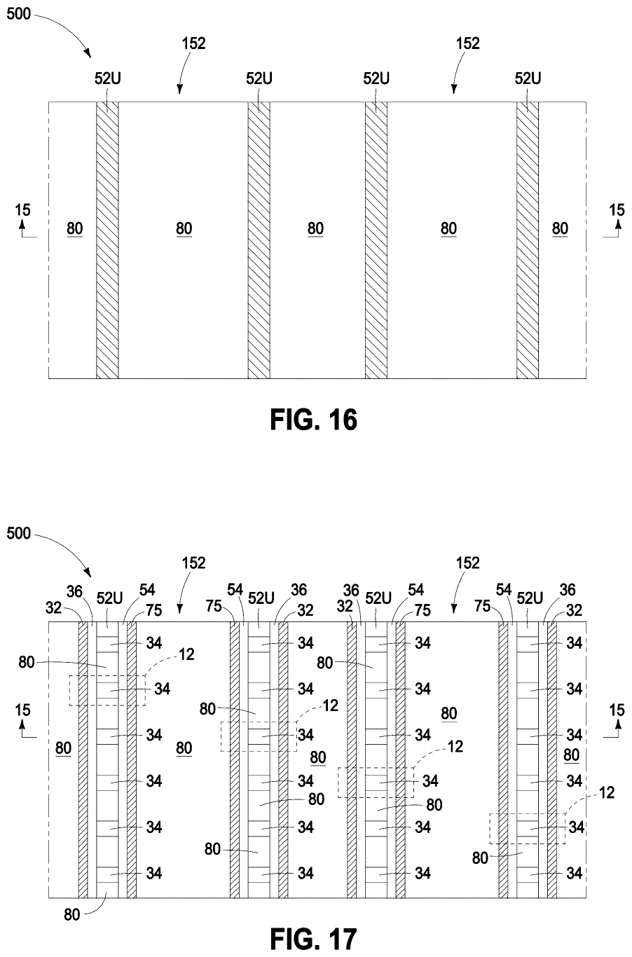

An example method of forming an array of memory cells in accordance with an embodiment of the invention is described with reference to FIGS. 4-17. The memory cells being formed in method will individually comprise a p-type transistor below an n-type transistor. The p-type transistor will comprise a control gate, charge-storage material, first channel material, charge-blocking material, and charge-passage material between the charge-storage material and the first channel material. A lower source/drain region of the n-type transistor will be directly electrically coupled to the charge-storage material of the p-type transistor. The n-type transistor will comprise a gate, second channel material, and gate insulator between the n-type-transistor gate and the second channel material. The control gate of the p-type transistor and the n-type-transistor gate will be directly electrically coupled together (for example as described above).

Referring to FIGS. 4 and 5, a predecessor construction to that of FIGS. 1 and 2 has been formed/patterned to comprise an array area 500 and a conductive structure 297 (e.g., connection 297) that will be common (i.e., directly electrically coupled) to at least some of the plurality of the p-type transistors being formed. Appropriately doped or undoped semiconductive material 22 (e.g., predominantly comprising silicon) is above conductive structure 297. A lowest portion thereof may be conductively doped (as indicated by stippling) to ultimately form second/lower source/drain regions 30 of the p-type transistors being formed, and which is directly electrically coupled to conductive structure 297. Semiconductive material 22, second/lower source/drain regions 30, and material of conductive structure 297 may be patterned at the same time/in the same masking step. Pitch multiplication may be used.

Insulative material 80 (e.g., silicon dioxide) has been formed between semiconductive material 22 and conductive structures 297, followed by planarizing such back to at least an outermost surface of semiconductive material 22. Conductive material for lower portion 52L of digitline 52* was subsequently formed, followed by formation of sacrificial material 150 there-atop (e.g., silicon nitride). Patterning thereof has occurred, thus forming openings 152, followed by fill of such openings with more insulative material 80 and etch-back thereof as shown.

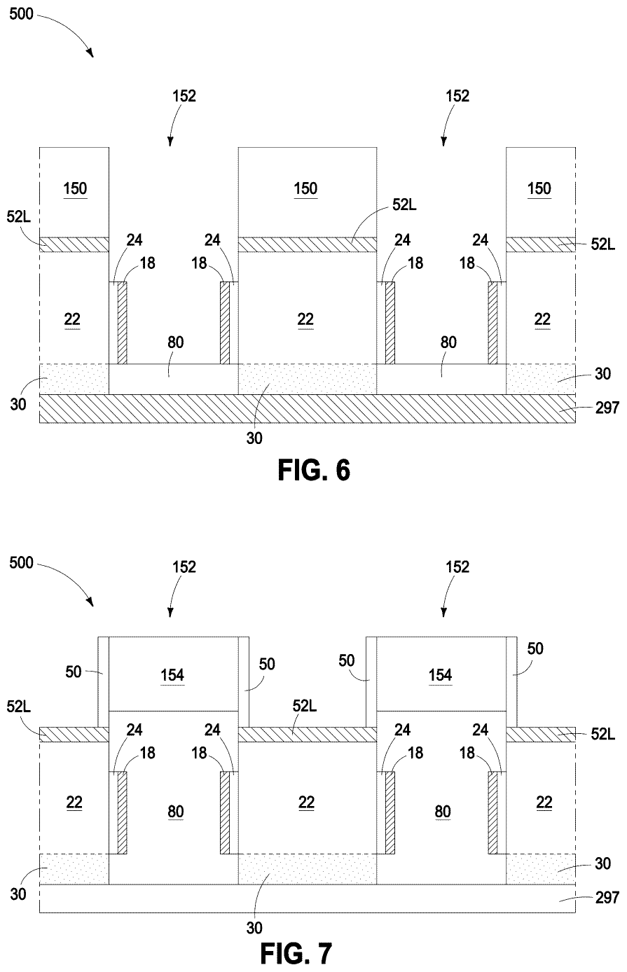

Referring to FIG. 6, lines of charge-blocking material 24 and lines (access lines/wordlines) of control gates 18 have been formed as shown.

Referring to FIG. 7, several processing steps have occurred. More insulative material 80 has been formed within openings 152 followed by planarizing such back to a top of sacrificial material 150 (no longer shown). Insulative material 80 was then etched back to the level shown, followed by formation of sacrificial material 154 (e.g., aluminum oxide) thereover, followed by planarizing such back to sacrificial material 150 (no longer shown) and which was subsequently removed (as shown). Thereafter, insulating material 50 was formed along the depicted sidewalls and anisotropically spacer-like etched as shown.

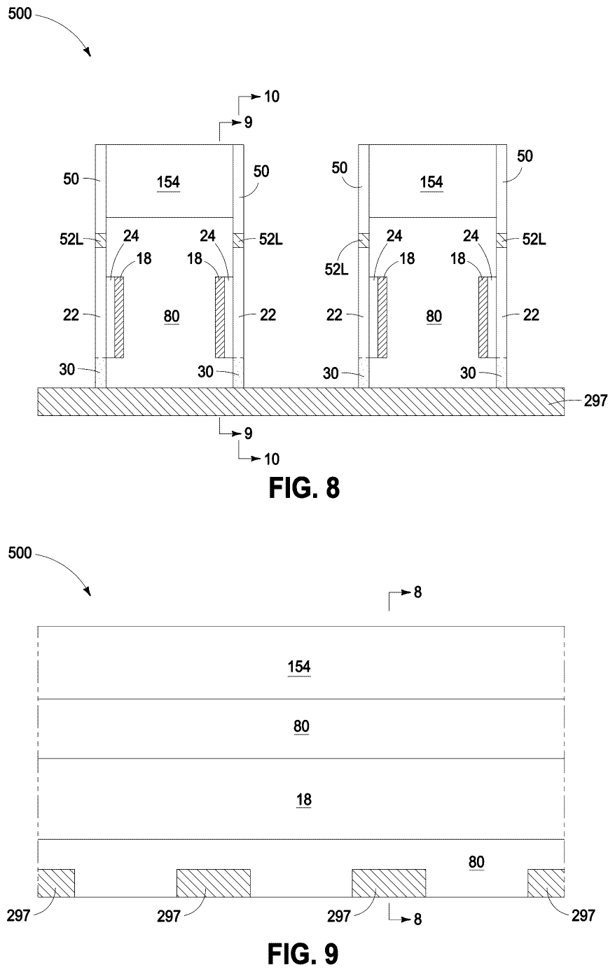

Referring to FIGS. 8-10, the material of lower portion 52L of digitlines 52* has been patterned as shown.

Referring to FIG. 11, more insulative material 80 has been formed and etched-back as shown to what will be bottom surfaces of charge-storage material 20 and charge-passage material 26. The latter have been subsequently formed as shown, followed by formation of more insulative material 80 and etching such back to the tops of charge-storage material 20.

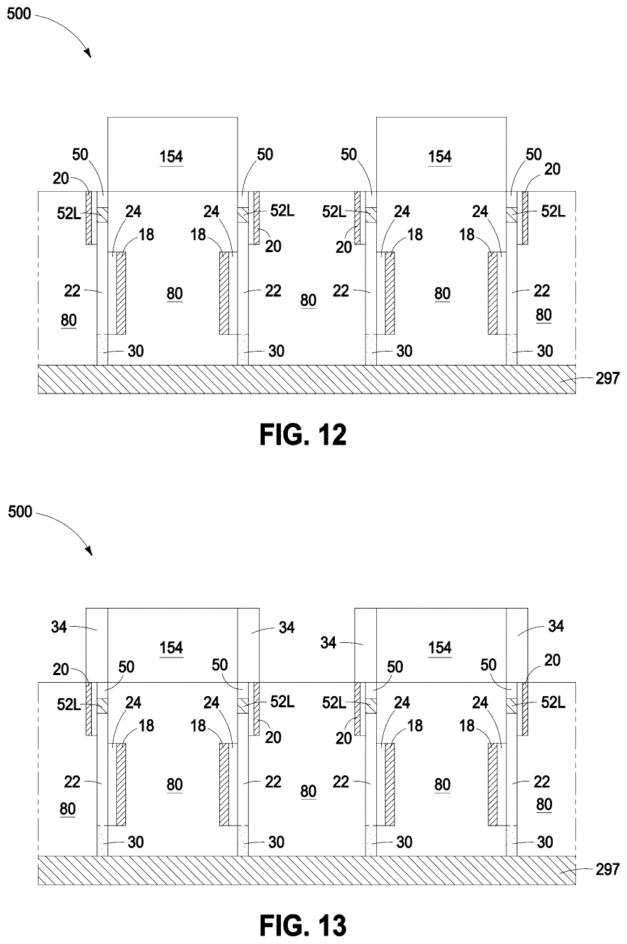

Referring to FIG. 12, insulating material 50 and charge-passage material 26 have been etched back.

Referring to FIG. 13, second channel material 34 has been formed.

Referring to FIG. 14, sacrificial material 154 (no longer shown) has been removed, followed by formation of gate insulator 36 and insulative material 54 (which may be of the same composition relative one another), followed by formation of conductive shield lines 75 and gates 32 (access lines/wordlines).

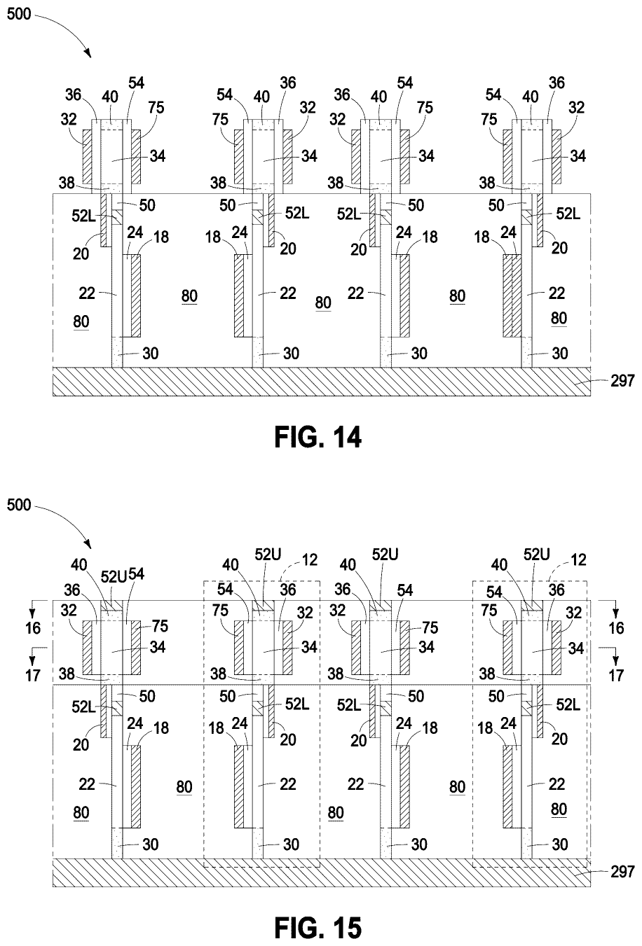

Referring to FIGS. 15-17, more insulative material 80 and upper portions 52U of digitlines 52* have been formed, thus forming memory cells 12 (only some of such being so-designated with dashed outlines). Outside of array area 500, multiple rows of shield lines could be connected (shorted) together (not shown) and access line and control gate lines connections made (not shown) on one or more side(s) of array area 500. Also outside of array area 500, individual upper portions 52U of digitlines 52* could be connected (shorted) to individual corresponding lower portions 52L of digitlines 52* (not shown) on another/other one or more side(s) of array area 500 adjacent the one side.

Accordingly, the above processing in a method embodiment, is but one example of forming a plurality of the p-type transistors 14 individually having a lower source/drain region 30 that is directly electrically coupled to a conductive structure 297 that is common to at least some of the plurality of p-type transistors 14. Second channel material 34 of individual n-type transistors 16 has been formed directly above first channel material 22 of individual of p-type transistors 16. Second channel material 34 may be considered as having two laterally opposing sides. Insulating material 50 is vertically between first channel material 22 and second channel material 34. Access lines WL* (each comprising one of gate 32 or gate 18) are formed on one of the two laterally opposing sides of second channel material 34. Individual of access lines WL* comprise n-type-transistor gate 32 of individual n-type transistors 16 or control gate 18 of individual p-type transistors 14. Conductive shield lines 75 are individually adjacent second channel material 34 on the other of the two laterally opposing sides of second channel material 34 as shown. Digitlines 52* are formed and are individually directly electrically coupled to a plurality of second/upper source/drain regions 40 of individual n-type transistors 16.

Any other attribute(s) or aspect(s) as shown and/or described herein with respect to other embodiments may be used.

Constructions and methods as described herein may enable denser memory circuitry than is in the prior art and than is shown in U.S. Patent Application No. 2024/0268091 to Karda et al. Further, in connection with a memory cell as shown in U.S. Patent Application No. 2024/0268091 to Karda et al., an important goal is high negative threshold voltage (V_{T}) on the p-type transistor and high positive V_{T} on the n-type transistor. In the '091 disclosure, a shield line 541B is shared by the p-type and n-type transistors. Shield is mainly desired for the n-type transistors to increase positive V_{T}, so the shared shield line is typically biased negatively. Since the shield line is negative and shared, the p-type transistor's hole barrier is lowered which effectively and undesirably reduces their V_{T}. Such can adversely impact “on” current (I_{ON}) and increase voltage swings for the p-type transistors. A conductive shield line that is adjacent the second channel material and not adjacent the first channel material may alleviate such issues. Additionally and/or alternately, vertically separating the gates for p-type and n-type transistors may enable use of different compositions for their respective charge-passage material and gate insulator, as well as conductive material of their gates, which may be advantageous. Further, the example construction where placing the charge-storage material and the control gate on opposite sides of the first channel material may be advantageous in operation.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The circuitry described herein (e.g., conductive vias thereof) may connect with circuitry that is on either the top or the bottom (i.e., either z-axis side) of a vertical stack regardless of orientation of the construction in three-dimensional space and which is not material to aspects of the inventions disclosed herein. For example, and by way of example only, conductive vias may connect with peripheral control circuitry that is beneath the stack with respect to the orientation shown in the drawings. As an alternate example, and by way of example only, conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, electronic components may be fabricated relative to the bottom of the stack with respect to the shown orientation but inverted therefrom during processing. Such electronic components may connect with conductive vias that extend through the stack to the substrate bonded with the other side that has such peripheral control circuitry. Regardless, constructions as shown and described herein may be processed, packaged, and/or mounted in any three-dimensional spatial orientation.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a memory cell comprises a p-type transistor and an n-type transistor. The p-type transistor comprises a control gate, charge-storage material, first channel material, charge-blocking material, and charge-passage material between the charge-storage material and the first channel material. A first source/drain region of the n-type transistor is directly electrically coupled to the charge-storage material of the p-type transistor. The n-type transistor comprises a gate, second channel material, and gate insulator between the n-type-transistor gate and the second channel material. The control gate of the p-type transistor and the n-type-transistor gate are directly electrically coupled together. A conductive shield line is adjacent the second channel material and not adjacent the first channel material.

In some embodiments, a memory cell comprises a p-type transistor and an n-type transistor. The p-type transistor comprises a control gate, charge-storage material, first channel material, charge-blocking material, and charge-passage material between the charge-storage material and the first channel material. A source/drain region of the n-type transistor is directly electrically coupled to the charge-storage material of the p-type transistor. The n-type transistor comprises a gate, second channel material, and gate insulator between the n-type-transistor gate and the second channel material. The n-type-transistor gate and the gate insulator are on a first side of the second channel material. The control gate of the p-type transistor and the n-type-transistor gate are directly electrically coupled together. A conductive shield line is adjacent the second channel material on a second side of the second channel material that is opposite the first side. The control gate of the p-type transistor and the n-type transistor gate are vertically spaced from one another.

In some embodiments, a memory cell comprises a p-type transistor and an n-type transistor. The p-type transistor comprises a control gate, charge-storage material, first channel material, charge-blocking material, and charge-passage material between the charge-storage material and the first channel material. A source/drain region of the n-type transistor is directly electrically coupled to the charge-storage material of the p-type transistor. The n-type transistor comprises a gate, second channel material, and gate insulator between the n-type-transistor gate and the second channel material. The control gate of the p-type transistor and the n-type-transistor gate are directly electrically coupled together. The control gate of the p-type transistor and the n-type transistor gate are vertically spaced from one another.

In some embodiments, a method is used in forming an array of memory cells. The memory cells individually comprise a p-type transistor below an n-type transistor. The p-type transistor comprises a control gate, charge-storage material, first channel material, charge-blocking material, and charge-passage material between the charge-storage material and the first channel material. A lower source/drain region of the n-type transistor is directly electrically coupled to the charge-storage material of the p-type transistor. The n-type transistor comprises a gate, second channel material, and gate insulator between the n-type-transistor gate and the second channel material. The control gate of the p-type transistor and the n-type-transistor gate are directly electrically coupled together. The method comprises forming a plurality of the p-type transistors. A lower source/drain region of individual of the p-type transistors is directly electrically coupled to a conductive structure that is common to at least some of the plurality of the p-type transistors. The second channel material of individual of the n-type transistors is formed directly above the first channel material of individual of the p-type transistors. The second channel material has two laterally opposing sides. Insulating material is vertically between the first and second channel materials. Access lines are formed on one of the two laterally opposing sides of the second channel material. Individual of the access lines comprise the n-type-transistor gate of the individual n-type transistors or the control gate of the individual p-type transistors. Conductive shield lines are formed that are individually adjacent the second channel material on the other of the two laterally opposing sides of the second channel material. Digitlines are formed that are individually directly electrically coupled to a plurality of upper source/drain regions of the individual n-type transistors.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A memory cell comprising:
a p-type transistor and an n-type transistor;
the p-type transistor comprising a control gate, charge-storage material, first channel material, charge-blocking material, and charge-passage material between the charge-storage material and the first channel material; a first source/drain region of the n-type transistor being directly electrically coupled to the charge-storage material of the p-type transistor;
the n-type transistor comprising a gate, second channel material, and gate insulator between the n-type-transistor gate and the second channel material; the control gate of the p-type transistor and the n-type-transistor gate being directly electrically coupled together; and
a conductive shield line adjacent the second channel material and not adjacent the first channel material.

2. The memory cell of claim 1 comprising insulative material between the conductive shield line and the second channel material.

3. The memory cell of claim 1 comprising:
a digitline that is directly electrically coupled to a second source/drain region of the n-type transistor and is electrically coupled through the first channel material of the p-type transistor to one source/drain region of the p-type transistor; and
the digitline comprising an upper portion directly above a lower portion, the upper portion being directly above and directly electrically coupled to the second source/drain region, the lower portion being directly against the first channel material of the p-type transistor, the upper and lower portions being directly electrically coupled together.

4. The memory cell of claim 3 wherein the lower portion is directly below the second channel material, an insulating material vertically separating the lower portion and the second channel material.

5. The memory cell of claim 3 wherein the upper portion is wider than the lower portion.

6. The memory cell of claim 3 wherein the lower portion is directly against a lateral side of the charge-passage material of the p-type transistor.

7. The memory cell of claim 3 wherein the second channel material is directly above the one source/drain region of the p-type transistor.

8. The memory cell of claim 7 wherein the one source/drain region of the p-type transistor is also directly above the first channel material of the p-type transistor.

9. The memory cell of claim 1 wherein the charge-storage material and the control gate of the p-type transistor are on opposite lateral sides of the first channel material.

10. The memory cell of claim 9 wherein the charge-storage material and the control gate are vertically spaced from one another.

11. The memory cell of claim 10 wherein the charge-storage material is above, but not directly above, the control gate.

12. A plurality of the memory cells of claim 1 in a memory array.

13. A memory cell comprising:
a p-type transistor and an n-type transistor;
the p-type transistor comprising a control gate, charge-storage material, first channel material, charge-blocking material, and charge-passage material between the charge-storage material and the first channel material; a source/drain region of the n-type transistor being directly electrically coupled to the charge-storage material of the p-type transistor;
the n-type transistor comprising a gate, second channel material, and gate insulator between the n-type-transistor gate and the second channel material; the n-type-transistor gate and the gate insulator being on a first side of the second channel material; the control gate of the p-type transistor and the n-type-transistor gate being directly electrically coupled together;
a conductive shield line adjacent the second channel material on a second side of the second channel material that is opposite the first side; and
the control gate of the p-type transistor and the n-type transistor gate being vertically spaced from one another.

14. The memory cell of claim 13 wherein the n-type transistor is directly above the p-type transistor.

15. The memory cell of claim 14 wherein the second channel material is directly above the first channel material.

16. The memory cell of claim 15 comprising insulating material vertically between the first and second channel materials.

17. The memory cell of claim 16 comprising a digitline that is directly electrically coupled to the first channel material of the p-type transistor, a portion of the digitline being directly under the insulating material.

18. A memory cell comprising:
a p-type transistor and an n-type transistor;
the p-type transistor comprising a control gate, charge-storage material, first channel material, charge-blocking material, and charge-passage material between the charge-storage material and the first channel material; a source/drain region of the n-type transistor being directly electrically coupled to the charge-storage material of the p-type transistor;
the n-type transistor comprising a gate, second channel material, and gate insulator between the n-type-transistor gate and the second channel material; the control gate of the p-type transistor and the n-type-transistor gate being directly electrically coupled together; and
the control gate of the p-type transistor and the n-type transistor gate being vertically spaced from one another.

19. The memory cell of claim 18 wherein the n-type transistor gate is above the control gate of the p-type transistor.

20. The memory cell of claim 19 wherein the n-type transistor gate is directly above the control gate of the p-type transistor.
